(19) United States
(12) Patent Application Publication
(10) Pub. No.: US 2012/0288698 A1
(43) Pub. Date: Nov. 15, 2012

(54) METHOD OF FABRICATION, DEVICE STRUCTURE AND SUBMOUNT COMPRISING DIAMOND ON METAL SUBSTRATE FOR THERMAL DISSIPATION

(75) Inventors: Nicolaie A. MOLDOVAN, Plainfield, IL (US); John Arthur Carlisle, Plainfield, IL (US); Hongjun Zeng, Naperville, IL (US)

(73) Assignee: Advanced Diamond Technology, Inc, Romeoville, IL (US)

(21) Appl. No.: 13/424,180

(22) Filed: Mar. 19, 2012

Related U.S. Application Data
(60) Provisional application No. 61/466,760, filed on Mar. 23, 2011.

(51) Int. Cl. H01L 23/373; H01L 21/50; B32B 33/00; C25D 1/00; B32B 7/12; B32B 9/04

(52) U.S. Cl. 428/216; 428/457; 428/141; 428/212; 205/67; 438/122; 361/709; 257/E21.499

(57) ABSTRACT

A method of fabrication, a device structure and a submount comprising high thermal conductivity (HTC) diamond on a HTC metal substrate, for thermal dissipation, are disclosed. The surface roughness of the diamond layer is controlled by depositing diamond on a sacrificial substrate, such as a polished silicon wafer, having a specific surface roughness. Following deposition of the diamond layer, an adhesion layer, e.g. comprising a refractory metal, such as tantalum, and at least one layer of HTC metal is provided. The HTC metal substrate is preferably copper or silver, and may be provided by electroforming metal onto a thin sputtered base layer, and optionally bonding another metal layer. The electrically non-conductive diamond layer has a smooth exposed surface, preferably ≦10 nm RMS, suitable for patterning of contact metallization and/or bonding to a semiconductor device. Methods are also disclosed for patterning the diamond on metal substrate to facilitate dicing.

### CROSS-REFERENCE TO RELATED APPLICATION(S)

This application claims priority from U.S. provisional patent application Ser. No. 61/466,760, entitled “Chip submounts made of diamond on metal substrates for thermal dissipation and method of fabrication” filed Mar. 23, 2011, by the present inventors, which is incorporated herein by reference, in its entirety.

### TECHNICAL FIELD

This invention relates to thermal management of devices using heatsinks and more particularly relates to fabrication of device structures and submounts comprising diamond on metal for thermal management of semiconductor devices, such as high power semiconductor devices.

### BACKGROUND ART

The reliability, performance, power consumption and other factors in the operation of high power semiconductor devices, such as high power Light Emitting Diodes (LEDs), high capacity Central Processing Units (CPUs), power amplifiers, and other devices, are often limited by thermal management capabilities for dissipation of heat generated by the device, i.e. heat handling and cooling. One of the principle problems is often the limited heat dissipation of the substrates on which these devices are mounted. To ameliorate this problem, an improved substrate would preferably have high thermal conductivity (HTC), and also be sufficiently electrically insulating. The material with the highest thermal conductivity is single crystal diamond (k_{diamond}≈2000 W/m·K), but it is usually considered to be too expensive for most applications. The thermal conductivity of polycrystalline diamond materials decreases with grain size. However, reasonably small grain sizes of ≧100 nm can still provide thermal conductivities greater than that of silver (k_{Ag}=406 W/m·K) or copper (k_{Cu}=385 W/m·K), which have the highest thermal conductivity among metals.

While silver is still quite expensive, combinations of diamond and copper-based materials have been long sought after as near optimal solutions for thermal dissipation problems in devices. The direct fabrication of such a thermal dissipator, by deposition of diamond onto a HTC metal, such as copper (Cu) or silver (Ag), is very challenging, due to large mismatches in linear thermal expansion coefficient (˜1.1×10⁻⁶ K⁻¹ for diamond, as compared to ˜16.7×10⁻⁶ K⁻¹ for Cu, and ˜18.9×10⁻⁶ K⁻¹ for Ag). Mismatch in thermal expansion and stress at the diamond metal interface can contribute to poor adhesion and delamination of the diamond layer from the substrate.

There are numerous known solutions for fabricating thermal dissipators comprising diamond on metals, but these solutions generally do not provide a suitable layer of diamond on copper, but result in rough diamond on diverse forms of copper-containing materials, as will be reviewed below. In this context, a rough diamond surface may be characterized by a surface roughness of 2 to 3 μm Root Mean Square (RMS) or more, which impedes the use of such layers for heat sinks or submounts for semiconductor devices. This is a particular problem when it is desirable to lithographically pattern metal leads and/or bond power chips to the diamond surface, and obtain good thermal contact. These rough diamond surfaces must therefore be polished, e.g. to nanometer scale roughness, for subsequent processing. However, polishing of the hardest and most chemically inert material known (diamond) is an expensive and technically demanding task. Alternative solutions to provide chip submounts comprising HTC diamond on metal, and particularly HTC diamond on copper, for thermal dissipation are therefore desirable.

U.S. Pat. No. 5,260,105 entitled “Aerosol-plasma deposition of films for electrochemical cells” to Wang, discloses brazing diamond to a Cu subcarrier using gold (Au). In particular, this solution uses an adhesion layer comprising a titanium/platinum/gold (Ti/Pt/Au) layer stack between the diamond and Cu, with the Ti adjacent the diamond; both the adhesion layer stack and the gold used for brazing are reported to impair, in part, the thermal conductivity of the resultant structure. The role of Ti in contact with diamond is as an adhesion layer, relying on the tendency of titanium carbide (TiC) to form at the interface between the Ti and the diamond. The disclosed method uses plasma jet deposition of diamond on top of a metal substrate and the adhesion layer, which usually results in a rough (hard to polish) diamond surface, and incorporation of hydrogen in the diamond, which further decreases thermal conductivity. A related patent, U.S. Pat. No. 5,492,770 entitled “Method and apparatus for vapor deposition of diamond film” to Kawarada et al. provides a method of deposition, by plasma jet, of both the diamond and the adhesion/transition layers onto a metal heat sink substrate. A mixture of reactants for forming the substrate material and the diamond layer are mixed in the plasma jet and deposited on the metal substrate prior to diamond deposition, to provide a transition layer. This method also results in surfaces with high surface roughness and thick transition layers, which have low thermal conductivity, i.e. significantly lower than diamond.

U.S. Pat. No. 6,641,861 entitled “Heatsink and fabrication method thereof”, to Saito et al., discloses fabrication of a heat sink through Chemical Vapor Deposition (CVD) of diamond onto a metal substrate made of sintered Cu and tungsten (W). After a brief selective etch of the Cu from the surface to leave a metal surface mostly composed of W, adhesion of the diamond is improved through the formation of a tungsten carbide (WC) compound at the interface. However, the sintered Cu and W substrate has a lower thermal conductivity than Cu and the resulting diamond surface has high surface roughness.

U.S. Pat. No. 7,531,020 entitled “Heat sink made from diamond-copper composite material containing boron, and method of producing a heat sink”, to Weber, discloses a heat sink substrate made by sintering a composite material composed of a mixture of diamond, Cu and boron, in which the boron serves to enhance the adhesion of diamond particles to Cu in the matrix. While such materials may have good thermal conductivity, they are not good electrical insulators and also have high surface roughness.

U.S. Pat. No. 7,841,428 entitled “Polycrystalline diamond apparatuses and methods of manufacture”, to Bertagnolli, discloses a method of forming a predominantly diamond layer (up to 90% by volume fraction) on a metal support by sintering diamond powder and fullerene mixtures at pressures of 48 kbar or higher, and at temperatures of 1160° C. or higher. The resulting material is not entirely diamond, has high surface roughness, and the material to which it may be bonded through the pressure sintering must be able to withstand the high temperature processing. Thus, the metal cannot be copper. It may for example, be iron or nickel, or a carbide of titanium, niobium, tantalum or vanadium.

Semiconductor-on-Diamond (SOD) substrates are also known. By way of example only, U.S. Pat. No. 7,846,767 entitled “Semiconductor-on-diamond devices and associated methods” to Sung, U.S. Pat. No. 7,875,934 entitled “Semiconductor substrate with islands of diamond and resulting devices” to Baskaran et al., and related patents, as well as articles in the scientific literature (e.g. Journal of Electronic Materials, Vol. 34, No. 7, 2005, p. 1089; Diamond & Related Materials 14, 2005, p. 308; J. Electrochem. Soc., Vol. 143, No. 4, April 1996, p. 1326; Appl. Phys. Lett, 97, 2010, p. 031904) disclose methods for fabricating and using SOD substrates for the purpose of enhanced heat dissipation from electronic structures. While the presence of diamond as a thin layer below the semiconductor (active) surface helps to dissipate the heat from the immediate proximity of the semiconductor junctions, this is a good solution only for thermal vias close to power structures. In addition, connections to an external heat sink to extract heat from the bulk of the SOD chip are typically a requirement. Thus, there is a need to address this last issue.

An article co-authored by the present inventors, relating to the fabrication of metal on diamond structures (Keun-Ho Kim et al., Small, 8-9, 2005, p. 866-874), discloses a process sequence for fabricating ultrananocrystalline diamond (UNCD) cantilevered structures comprising pyramidal Atomic Force Microscopy (AFM) probes by depositing UNCD diamond on a silicon substrate that forms a mold for the UNCD probe tips and cantilever; electroforming a metal chip handling body, such as a layer of nickel, chromium or gold on the diamond structure with an adhesion layer comprising Ti, and then removing the underlying silicon to release the structure. While this article provides diamond layers with low surface roughness, this is achieved with UNCD diamond layers with grain sizes from 2-5 nm. Such small grain sizes are required to provide a small AFM tip radius. However, this small-grained UNCD diamond material does not provide sufficient thermal conductivity for thermal dissipation as compared to larger grain HTC diamond.

In summary, layers of high thermal conductivity (HTC) diamond require relatively large grain sizes, e.g. ≧100 nm to provide sufficient thermal conductivity and thus, known methods of fabrication, such as CVD, result in significantly rough films (typically surface roughness of ˜2-3 μm RMS). It will be appreciated, for example, that fabricating metallization leads and bonding of semiconductor devices or electronic chips on such rough surfaces is challenging. Polishing of such rough diamond films to the required nanometer scale roughness, although possible, is a long and costly process.

Thus, there is a need for improved or alternative solutions which address the shortcomings of known structures and methods.

### SUMMARY OF INVENTION

The present invention seeks to ameliorate the above mentioned problems, or at least provide an alternative method for fabrication of structures comprising diamond on metal for heat dissipation.

Thus, the present invention provides a method of fabrication, a device structure and a submount comprising diamond on metal for thermal dissipation, which overcomes at least some of the above mentioned problems.

A first aspect of the invention provides a method for fabricating a device structure comprising diamond on metal substrate for thermal dissipation, by steps comprising: providing a sacrificial silicon substrate having a surface of a selected surface roughness; providing thereon a layer of high thermal conductivity (HTC) diamond; providing an adhesion layer on the layer of diamond; providing at least one layer of high thermal conductivity (HTC) metal to form an HTC metal substrate; and removing the sacrificial substrate.

By forming the diamond layer on a polished sacrificial silicon substrate, after removal of the silicon substrate, the exposed surface of the diamond layer (i.e. a device mounting surface) has a surface roughness substantially similar to that of the surface of the sacrificial substrate. Preferably, providing the layer of HTC diamond comprises depositing a layer of non-conductive (undoped) HTC diamond, having a grain size ≧100 nm on a sacrificial substrate having a surface roughness of <10 nm RMS.

Preferably, the at least one HTC metal layer is selected from the group consisting of copper, silver, an alloy of copper, an alloy of silver, and a copper-silver alloy. The adhesion layer may comprise a metal selected from the group consisting of tantalum, niobium, titanium, molybdenum, tungsten, other metals having good adhesion to diamond, and mixtures thereof. Tantalum is preferred because it is more ductile and adapts to stress by plastic deformation. The step of providing at least one layer of HTC metal to form a metal substrate may comprise depositing a first layer of HTC metal on the adhesion layer as a plating base layer and electroforming a second layer of HTC metal on the base layer. The method may further comprise planarizing, e.g. polishing, the surface of the resulting second layer of HTC metal. Alternatively, the metal substrate may be formed using a thinner second layer of electroformed metal, and then, after polishing, bonding another metal layer, such as a pre-fabricated HTC metal substrate or a metal plate.

Advantageously, the step of providing an adhesion layer comprises sputtering the adhesion layer; and the step of depositing the first layer of HTC metal comprises sputtering the first layer of HTC metal onto the adhesion layer as a plating base layer, without breaking vacuum. The method may further comprise pre-cleaning or pre-conditioning the diamond layer before depositing the adhesion layer to ensure good adhesion.

In a preferred embodiment, a method is provided for fabricating a device structure for a submount comprising HTC diamond on a HTC copper substrate. More preferably the adhesion layer is sputtered tantalum, the first HTC layer is sputtered copper, and the second HTC layer comprises electroformed copper. The sputtered copper layer acts as a plating base layer for electroforming an overlying second, much thicker copper layer to form the HTC metal substrate, or electroforming a thin layer of copper, and after planarizing or polishing, bonding a prefabricated, and optionally pre-patterned, thicker layer of copper.

The diamond layer may be provided with a thickness from 3 μm to 30 μm and the adhesion layer may have a thickness from 2 nm to 500 nm. The copper substrate may be provided with a thickness from 500 μm to several mm, i.e. to form a self-supporting metal substrate. After removal of the sacrificial substrate, the exposed surface, or device mounting surface, of the HTC diamond layer preferably has a surface roughness of ≦10 nm, preferably ≦5 nm and more preferably ≦2 nm RMS.

Advantageously, the step of providing a layer of HTC diamond comprises: masking or patterning the sacrificial substrate; and selectively growing or depositing a patterned layer of HTC diamond on the sacrificial substrate. Patterning of the diamond layer and the metal substrate, i.e. to define individual heat dissipation structures, facilitates dicing or further processing steps, and preferably avoids the need to etch or cut through the diamond layer. To provide the metal substrate, the first layer of HTC metal may be selectively masked before deposition of subsequent layers of HTC metal, preferably with a polymer grid or form, to define a plurality of individual heat dissipation structures. After defining individual heat dissipation structures, the method may comprise bonding a removable carrier layer thereto, before removing the sacrificial substrate layer.

The method may further comprise steps of thermally coupling and electrically connecting a semiconductor device, e.g. by defining contact metallization on the diamond surface, and electrically connecting the semiconductor device to the metallization, or bonding the semiconductor device to the diamond surface. Thus, methods according to preferred embodiments provide for fabrication a device structure comprising a diamond on metal thermal dissipation structure, such as a chip submount.

A second aspect of the invention provides a device structure for thermal dissipation comprising: a layer of high thermal conductivity (HTC) diamond having a grain size of greater than ≧100 nm on a HTC metal substrate; the diamond layer having a device mounting surface and an interface with the HTC metal substrate comprising an adhesion layer; and the interface of the layer of HTC diamond with the HTC metal substrate having a surface roughness substantially larger than the surface roughness of the device mounting surface of the HTC diamond layer.

While the diamond to metal interface may have a surface roughness of several μm RMS, preferably, the device mounting surface of the diamond layer has a surface roughness <10 nm RMS, preferably ≦5 nm and more preferably ≦2 nm. In particular, a preferred embodiment of the present invention provides a device structure, or a submount, comprising a layer of high thermal conductivity (HTC) diamond on a HTC metal, preferably copper or silver. The diamond metal interface comprises an adhesion layer of a refractory metal or other metal having a good adhesion to diamond and the adhesion layer is preferably tantalum. The diamond layer is preferably undoped and non-conductive, and has a thickness from about 3 μm to 30 μm.

This structure is achieved by depositing the diamond on a sacrificial smooth substrate, such as a polished silicon wafer, so that the diamond layer must conform to the underlying smooth sacrificial substrate surface. The rougher surface that forms as the diamond layer is grown or deposited eventually forms the interface with the HTC metal substrate. Thus, this rough surface of the diamond layer is buried in the metal, where it does not hinder device functionality or subsequent processing. This method of fabrication avoids the need for direct deposition of diamond on copper, and allows for depositing copper by electroplating or electroforming onto a diamond-coated silicon wafer comprising an intermediary adhesion and plating base layer. After removal of the silicon substrate, it provides a diamond layer with a smooth exposed surface, as deposited, with surface roughness determined by the sacrificial substrate, without the need for slow and expensive polishing.

This resulting HTC diamond on HTC metal structure may be used as a submount for a heat-dissipating device, such as a high power semiconductor chip, to facilitate heat transfer between the chip and an underlying PCB circuit board (or other type of circuit board) on which it is mounted. The HTC diamond layer induces rapid lateral heat diffusion of the heat in the diamond layer, away from the heat source (i.e. a high power chip), while the HTC metal substrate conducts the heat away through the body of the submount, perpendicular to the diamond-coated surface, to a larger external cooling system or heatsink to which it may be attached. Attachment of chips directly to metal is not desirable (to avoid an electrical short-circuit) and the electrically insulating diamond is a better heat conductor than the underlying HTC metal. A layer of a few microns of large grain HTC diamond provides an excellent, and less expensive, alternative to using bulk diamond as a thermal dissipation substrate or submount. Simulations and measurements show that a stack of a few microns of diamond on top of a high thermal conductivity metal (e.g. Cu or Ag) plate forms a thermal dissipater able to lower, by tens of degrees C, the resulting operating temperature of the chip, at the same dissipated power. For high power LEDs, this would allow a 35 times improvement in power density handling for diamond-based devices as compared to those fabricated on silicon substrates and ˜14 times better than those fabricated on silicon carbide (SiC) substrates.

Other aspects of the invention provide a chip submount for thermal dissipation fabricated by method steps as described herein, and a device structure comprising a high power semiconductor device coupled to a chip submount fabricated by method steps as described herein.

High power semiconductor chips may be bonded to the diamond, e.g. via a thin film metal layer or electrode. The diamond layer contributes to fast lateral heat dissipation and the copper substrate conducts the heat further away from the heat source, towards a heat sink. Metallization traces may be produced on top of the diamond, for example, by known prior art lithographic patterning processes.

A further aspect of the invention provides a method for forming a device structure for thermal dissipation comprising a HTC diamond layer having a surface of a selected surface roughness, comprising: providing a sacrificial substrate having a surface of the selected surface roughness; providing thereon a layer of HTC diamond; providing at least one layer of a HTC material to provide a substrate; and removing the sacrificial substrate to expose a diamond surface of the selected surface roughness on a HTC substrate. Providing at least one layer of a HTC material may comprise depositing on the HTC diamond layer an adhesion layer and at least one layer of HTC material comprising a metal as described above, or at least one layer of a HTC composite material such as: Cu-diamond, Ag-diamond, carbon nanotube or graphene platelets-based nanocomposites, together with or instead of copper and/or silver.

Thus, a method of fabrication, a device structure, a submount comprising diamond on metal, and more particularly diamond on copper, are provided, which address at least some of the problems mentioned above.

The foregoing and other objects, features, aspects and advantages of the present invention will become more apparent from the following detailed description, taken in conjunction with the accompanying drawings, of preferred embodiments of the invention, which description is by way of example only.

### BRIEF DESCRIPTION OF DRAWINGS

In the drawings, identical or corresponding elements in the different Figures have the same reference numeral.

FIGS. 1a to 1f illustrate schematically process steps for fabricating a semiconductor device structure comprising a diamond on copper substrate for thermal dissipation, according to a first embodiment of the present invention;

FIGS. 2a to 2h illustrate schematically process steps for fabricating a semiconductor device structure comprising a diamond on copper substrate for thermal dissipation, according to a second embodiment;

FIGS. 3a to 3k illustrates process steps for fabricating a semiconductor device structure comprising a diamond on copper substrate for thermal dissipation, according to a third embodiment;

FIGS. 4a to 4c illustrate process steps for fabricating a semiconductor device structure comprising a diamond on copper substrate for thermal dissipation according to an alternative embodiment; and

FIG. 5 shows a schematic enlarged cross-sectional view through the diamond layer and underlying metal substrate illustrating the relative roughness of the as-deposited diamond surface and the diamond-metal interface.

### DESCRIPTION OF PREFERRED EMBODIMENTS

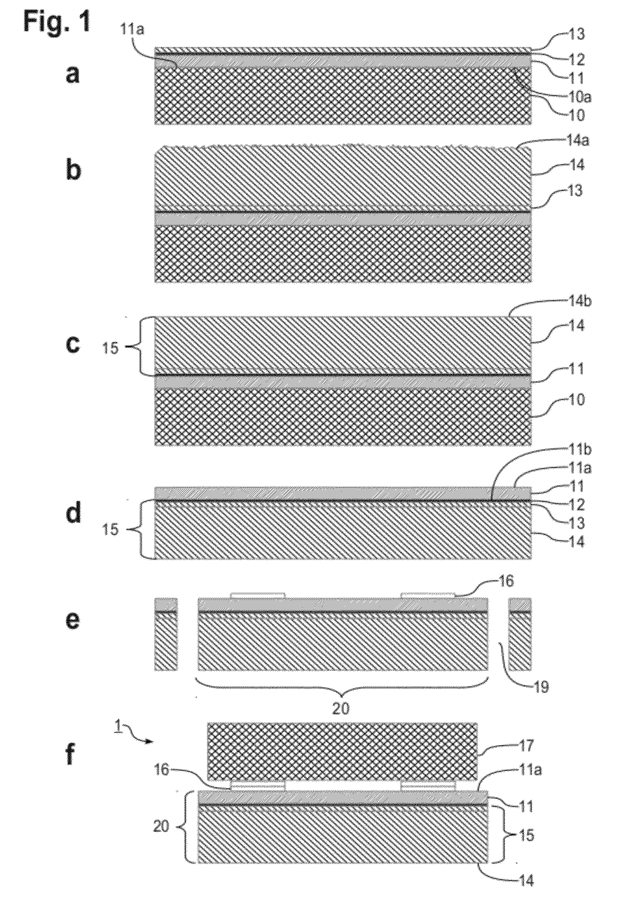

A method of fabricating a device structure 1 comprising a diamond on metal substrate or submount 20 according to a first embodiment of the invention is illustrated in FIGS. 1a to 1f. The resulting device structure 1, shown in FIG. 1f, comprises a high power semiconductor device or chip 17 and a chip submount 20 comprising an HTC metal substrate 15 and a top layer 11 of HTC diamond, which has a smooth surface 11a of a required surface roughness, preferably <10 nm RMS or less. In particular, the HTC diamond layer preferably has a grain size in the range from about 100 nm to 3 μm to provide the required thermal conductivity, and is preferably undoped and non-conductive (electrically insulating). Metal contacts or electrical leads 16 are defined on the diamond surface 11a for bonding the chip 17 to the diamond layer 11. In this embodiment, the metal substrate 15 is preferably copper and it comprises a thin first layer 13 of deposited copper, e.g. sputtered copper, which forms a plating base layer for a thicker second layer of electrodeposited copper 14. An adhesion layer 12 comprising a layer of sputtered Ta is provided between Cu layer 13 and the HTC diamond layer 11.

By using a fabrication sequence including a sacrificial polished silicon substrate, a layer 11 of larger grain size diamond having a sufficiently high thermal conductivity can be fabricated with a smooth mounting surface 11a. That is, the exposed diamond surface 11a of the diamond layer can be provided with a nanometer scale surface roughness, while the relatively rough surface 11b forms the diamond-metal interface.

The fabrication process starts from a smooth sacrificial silicon substrate, i.e. a Si wafer 10 (see FIG. 1a), preferably of crystallographic orientation other than (111), to avoid difficulties in its removal in later steps. The quality of the Si wafer can be low, including wafers made of polycrystalline Si or even metallurgical grade silicon. However the silicon surface 10a on which the diamond is to be deposited must have a sufficiently smooth surface, i.e. typically a surface roughness of <10 nm RMS, or more preferably <5 nm RMS, or <1 nm RMS. The deposition of a high thermal conductivity (HTC) diamond layer 11, with grain sizes in the range e.g. 100 nm to 1 μm, or 500 nm to 3 μm can be performed by chemical vapor deposition (CVD) methods, as described, for example, in U.S. Pat. No. 7,128,889 entitled “Method to grow carbon thin films consisting entirely of diamond grains 3-5 nm in size and high-energy grain boundaries” to Carlisle et al. and US patent publication number 20090017258 entitled “Diamond Film Deposition” to Carlisle et al.

The HTC diamond layer may have a thickness on the order of several microns or more, e.g. in the range from 3-5 μm, to 5-15 μm, to 15-30 μm or higher. This layer of HTC diamond should be electrically non-conductive (i.e. undoped). The resulting surface 11a of the deposited HTC diamond layer 11 conforms to the silicon substrate, while the surface 11b of the diamond layer may be relatively rough, e.g. several microns RMS. The adhesion layer 12 is then deposited on the diamond surface 11b. The adhesion layer 12 is preferably thin relative to the thickness of the diamond layer, i.e. in a range of 2 to 500 nm, and more preferably in the range of 2 to 50 nm, in thickness. The adhesion layer is in this embodiment is sputtered tantalum. The adhesion layer is preferably a metal, e.g. a refractory metal such as tantalum (Ta), niobium (Nb), titanium (Ti), Tungsten (W), molybdenum (Mo), or other metal with good adhesion to diamond, that may be deposited by sputtering or other thin film deposition processes. Tantalum is preferred. Niobium is a less expensive alternative to tantalum, and also has good ductility and adhesion to diamond. Suitable deposition processes may include, but are not limited to: sputtering, evaporative, laser, electrospray, arc, molecular beam epitaxy, and other suitable processes. To enhance adhesion of the adhesion layer 12 to diamond, a surface pre-treatment may be performed, such as, a high temperature (100-120° C.) sulphuric acid bath treatment followed by deionized (DI) water rinsing, a plasma activation, a short ion beam milling or a combination of the above, may be performed before deposition of the adhesion layer 12. The first HTC metal layer 13 is relatively thin, e.g. 50-500 nm, and acts as a plating base layer for subsequent deposition, of a thick second HTC metal layer 14. In this embodiment, both first and second HTC metals are copper. The first HTC metal layer 13 is preferably also deposited by sputtering, without breaking the vacuum in the sputtering chamber after deposition of the adhesion layer 12, i.e. to ensure good adhesion of the tantalum and copper.

As shown in FIG. 1b, a relatively thick layer 14 of the second HTC metal, i.e. Cu is electrodeposited onto the plating base. The first HTC metal for the plating base layer 13 is preferably matched in thermal expansion coefficient and/or chemical similarity, and most preferably is substantially the same metal as that used for the electrodeposited second HTC metal layer 14. The thickness of this HTC metal 14 is such that it produces a self-supporting solid substrate 15 comprising the metal layers 13,14 and 15 which is typically in the range of 500 μm to a few mm (see FIG. 1d in which the resulting structure is inverted relative to FIG. 1c).

To avoid spurious electroplating of HTC metal on the back side of the Si substrate wafer, it can be coated with an insulating layer (e.g. photoresist, SiO₂, SiN_{X}, or insulating tape) or protected with a special holder. The latter is preferred, in order to assure a more uniform electric field in the electrolyte solution and avoid deposition anomalies at the contact point of the electrode to the wafer. A preferred option is to use a Si wafer coated with a conductive film (e.g. sputtered metal) on the back side and contacted on the back in a central location with a pin contact from an electrically insulating protective holder, in order to insulate the wafer back side, the pin, and the wires from conducting current through the electrolyte solution. Other options are to use wax, tape or other means to prevent the electrodeposition of HTC metal on unwanted areas, and also to improve the uniformity of coating on the wafer front side.

The electrolyte solution for depositing the HTC metal layer 14 can be a copper sulfate (CuSO₄) solution, adjusted to an acidic pH (and suitable conductivity) with sulfuric acid (H₂SO₄). Deposition can be performed at a current density of 0.5-10 mA/cm² or as is known in the art for copper electrodeposition. The electrolyte solution is preferably continuously filtered using a pump and a filter unit, and thermostated for improved deposition uniformity.

Since the electrodeposited metal layer 14 is usually rough and un-even at the surface 14a (FIG. 1b), it needs to be planarized or smoothed (FIG. 1c), e.g. by mechanical machining (for example, by fly cutting, milling, polishing) or laser vaporization, surface pressure deformation, or other suitable method. This results in a metal layer 14 having a smooth metal surface 14b. The next step is the removal of the sacrificial Si substrate layer 10 (FIG. 1d) to leave the diamond layer 11 supported by the metal substrate 15. This can be done by well-known mechanical or chemical methods, for example, by grinding, polishing, chemical-mechanical polishing (CMP), chemical etching, or a combination thereof. Chemical etching, such as with potassium hydroxide (KOH) solution (typically 30-50%, at 70-100° C.) may be used. Other methods of silicon removal can include use of tetramethylammonium hydroxide (TMAH), ethylenediamine pyrocatechol (EDP) or others, as known to those skilled in the art. In the latter case, it is convenient to protect the Cu side with a special holder or wax, to avoid staining and/or corrosion of the HTC metal layers 13 and 14 or the adhesion layer 12. Removal of stains from the Cu face 14b can be accomplished with low concentration acid (H₂SO₄, 2-5%) baths, followed by rinsing and drying.

After removal of the sacrificial silicon substrate 10, the resulting exposed surface 11a of the large grain diamond layer 11 has a smooth surface, effectively “molded by” or conforming to the polished surface 10a of the silicon substrate 10 on which it was deposited.

Electrical leads or conductive contacts 16 are provided for bonding the device, e.g. a high power semiconductor chip 17 to the diamond surface 11a. Contacts 16 may be formed on top of the diamond surface as shown in FIG. 1e, by standard microfabrication methods, such as metal film deposition-lithography-etching, or by lithography-metal deposition-lift-off, as well known to those skilled in the art. Adhesion between the diamond surface 11a and metal leads 16 can be enhanced by surface treatment of the diamond layer 11 before deposition of the metallization layer 16 or by use of an adhesion layer (not shown). For example: to enhance adhesion of the contact metal 16 to diamond, a high temperature (100-120° C.) sulphuric acid bath treatment followed by deionized (DI) water rinsing, a plasma activation, a short ion beam milling, or a combination of the above may be used before the metal deposition.

Dicing the substrate, e.g by cutting dicing streets 19 to create a plurality of thermal dissipation structures or submounts 20 (FIG. 1e), of desired sizes, can be performed either before or after the formation of the conductive leads 16. Preferred dicing methods are laser dicing or abrasive jet dicing. Alternatively, the diamond layer can be patterned by reactive ion etching (RIE) or inductively-coupled plasma RIE (ICP-RIE) through a silicon dioxide (SiO₂) or other hard mask (e.g. 1-3 μm thick) as described by Moldovan et al. (Journal Vac. Sci. Technology, B, 27 (6) pp. 3125-2121, 2009), prior to dicing, to avoid dicing through the hard material. A thicker hard mask layer may be required for thicker diamond films. That is, the etch rate selectivity of the ICP-RIE process may not be sufficient if a relatively thin (˜1 um) layer of SiO₂ is used as a mask with a relatively thick diamond layer (˜>5 um). Alternative dicing methods are presented in the second embodiment.

The resulting structure of the thermal dissipation submount 20 is shown in FIG. 1e.

As shown in FIG. 1f, a semiconductor device such as high power chip 17 can be attached to contacts 16 on the submount 20 by known methods, such as, solder bumps (flip-chip technology), thermo-compression bonding, or by transfer printing. If, alternatively, the attachment of the chip to the submount is performed directly onto the diamond, without intervening metal, electrical connections would then have to be made by another method, e.g. by wire bonding or by bonding a metal-patterned substrate to the diamond surface.

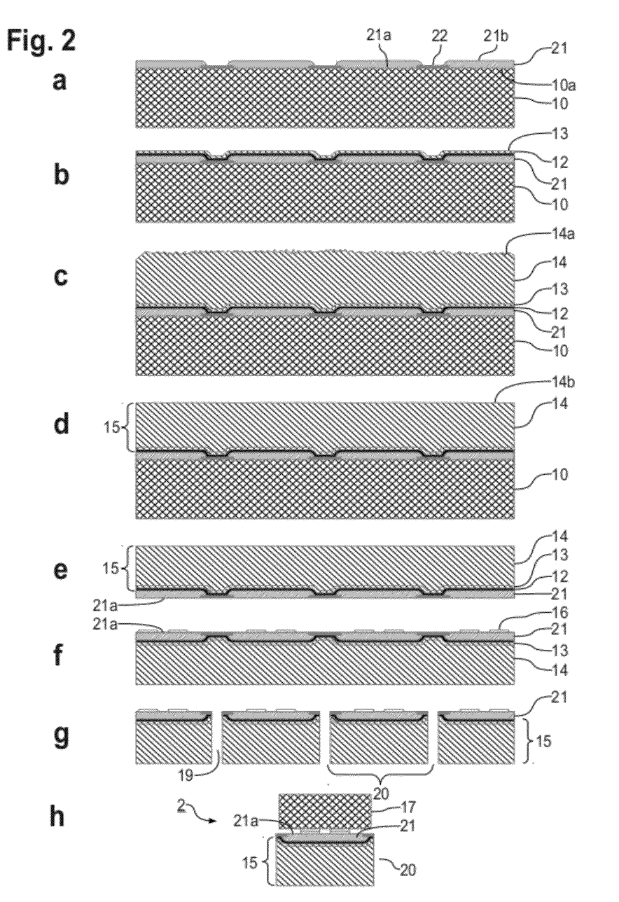

A method for fabricating a device structure 2 according to a second embodiment of the invention is illustrated schematically in FIGS. 2a to 2h, and comprises selectively forming diamond areas 21 on the smooth silicon substrate 10 and selectively forming the HTC metal substrate layer 15 on the diamond areas 21. This process sequence avoids the need for dicing through the thick HTC metal layer and the underlying diamond layer, or avoids the requirement for etching through the diamond layer 10 when the diamond layer is on the Cu substrate. This is desirable because ICP-RIE or RIE etching of diamond down to the Cu substrate may generate Cu contamination of the etch reactor chambers. If this must be avoided, the fabrication sequence presented in FIG. 2 can be followed.

This process sequence begins with the formation of a mask or patterned layer 22 on the surface 10a of a Si wafer substrate 10 as shown in FIG. 2a, to provide for selective growth or deposition of diamond thereon. This can be done by one of the following selective seeding and/or growth methods:

a) Seeding a blank Si wafer, coating it with photoresist, patterning the photoresist by lithographic means, followed by removal of seeds in the photoresist openings (by oxygen (O₂) plasma etching, or slight etching of the substrate by wet chemical means, followed by selective CVD deposition of HTC diamond only in the areas with seeds which were left-over in the areas covered with photoresist.
b) An alternative method is to start from a Si wafer with a protective SiO₂ (or other) layer on top, patterning it by lithographic means, seeding the wafer, removing the protective layer completely or partially (the later as presented in FIG. 2a), and growing the HTC diamond by CVD.
c) Yet another method is to start by depositing a very thin (50-500 nm) HTC diamond film on a Si substrate, depositing a hard mask (such as PECVD SiO₂, or Ni, or Al, or simply photoresist or other), patterning the hard mask lithographically, etching the thin HTC diamond layer by RIE, removing the hard mask, then continuing the growth of HTC diamond by CVD to the desired thickness.
d) Any combination of a), b) and/or c) above.

Following selective growth or deposition of the patterned layer of HTC diamond 21, an adhesion layer 12 and a plating base layer 13 are deposited (FIG. 2b) on surface 21b of the diamond layer, and then the thick HTC metal 14 is electrochemically deposited thereon (FIG. 2c). Layers 12, 13 and 14 are provided using processes similar to those described for the first embodiment. As described above, the rough top surface of the electrodeposited HTC metal layer 14 is machined/polished to provide a flat surface 14b (FIG. 2d) and the Si substrate 10 is removed (FIG. 2e) to expose surface 21a of the patterned diamond layer 21. Metallic contact leads 16 are fabricated on top of the diamond surface 21a (FIG. 2f). Dicing of submounts 20 can be performed more conveniently in this embodiment (FIG. 2g), and comprises cutting only through the HTC metal substrate layers 15, and any masking or patterning layer 22. The dicing streets 19 are free of diamond because of the design of the mask or patterning used for selective seeding. Subsequent steps for bonding of the high power chip 17 to the diamond surface 21a of the submount 20 are similar to those of the first embodiment and result in the device structure 2 as shown in FIG. 2h.

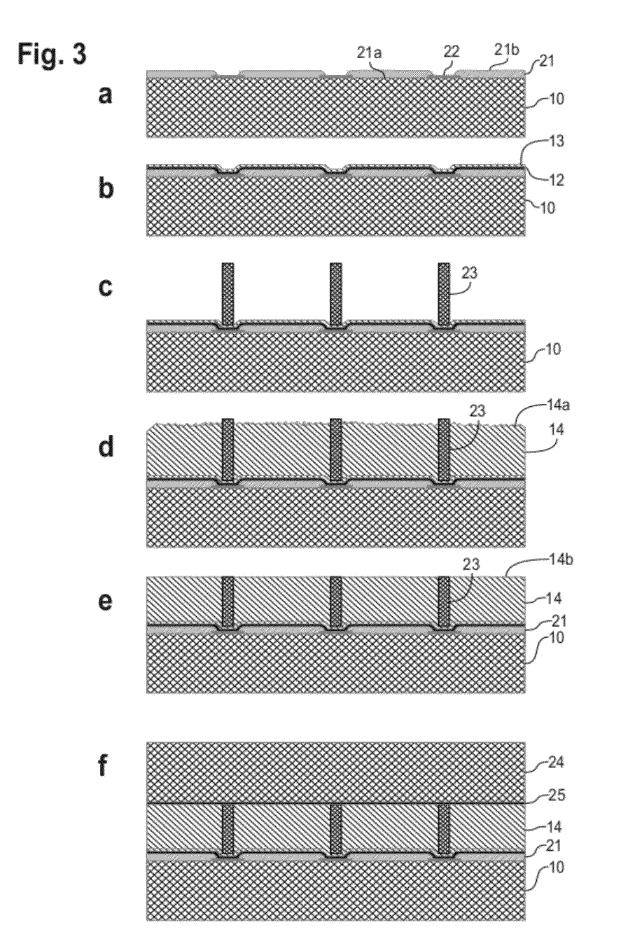

A method according to a third embodiment of the invention completely avoids the need for dicing through the thick HTC metal layer 14. As illustrated in FIG. 3, the method comprises patterned growth of HTC diamond 21 on the surface 10a of the Si substrate wafer 10 (FIG. 3a); deposition of an adhesion layer 12; and deposition of a plating base of first HTC metal layer 13 (FIG. 3b), by steps similar to those of the second embodiment. Subsequently, a thick mold or mask 23 (ideally about 10-20% thicker than the future electroplated HTC metal 14 to avoid overplating) is microfabricated (FIG. 3c). This can be done by using a thick photoresist layer (such as SU-8, Microposit, or other) and optical lithography, deep X-ray lithography with an acrylic resist layer, or by simply gluing a polymer grid or form onto the work surface using an adhesive. An O₂ plasma descum is recommended in order to obtain a clean plating base surface, prior to electroforming. Then, steps for electroforming of a thick HTC metal layer 14 (FIG. 3d), smoothing and polishing its surface 14a (FIG. 3e) follow, using processes similar to those described in the previous embodiments.

A temporary carrier wafer 24 is temporarily bonded to the polished HTC metal surface 15 using a removable adhesive 25 (such as WaferBOND, Brewer Science) and equipment and processes well known to those skilled in the art of back end processing of (thin) Si wafers (FIG. 3f). Subsequently, the initial Si substrate 10 is removed, by methods similar to those described in the previous embodiments (FIG. 3g). Conductive leads 16 are lithographically fabricated on top of the free HTC diamond surface 21a (FIG. 3h), as described in the previous embodiments. The carrier wafer 24 is then removed using heat to melt the temporary bonding layer 25 using debonding equipment and procedures as known to those skilled in the art. A free standing array of submounts 20 is obtained, in which the submounts are weakly attached to each other via the polymer mold 23 and the adhesion and plating base layers 12 and 13 respectively (FIG. 3i). The mold polymer 23 is then dissolved in suitable remover solutions (e.g. SU-8 remover, Microposit, for SU-8 resist molds, or methylene chloride, acetone, or NMP 1165 remover for acrylic molds), resulting in loose submount chips 20 (FIG. 3j). The submount chips 20 are then solvent cleaned and dried, and are then ready to be bonded to high power device chips 17, e.g. by one of the methods described in the previous embodiments, to provide a device structure 3 (FIG. 3k) that is similar to device structure 2 (FIG. 2h).

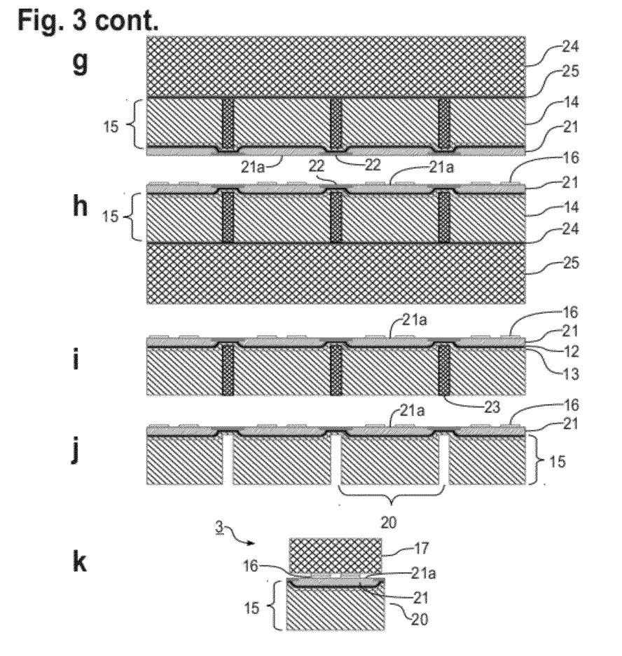

According to yet another embodiment, as illustrated in FIGS. 4a to 4c, an alternative method is provided for fabricating the HTC metal substrate 15. The initial steps of fabrication are similar to those of the first and second embodiments, for example, as described with reference to FIG. 1a or FIGS. 2a and 2b. That is the method comprises providing a smooth silicon substrate, providing a diamond layer 11 (FIG. 1a) or patterned diamond layer 21 (FIG. 2a) thereon, and then providing an adhesion layer 12 and a first HTC metal layer 13 as a base plating layer. Then, a second layer of HTC metal 14 is provided comprising a relatively thin layer (e.g. 100 μm-500 μm) of electroplated HTC metal. This thin electrodeposited layer 14 is then polished to provide a flat the surface 14b (FIG. 4a) for bonding to a thicker third HTC metal substrate, such as a metal plate 40 (FIG. 4a), by a process, such as, thermo-compression bonding or soldering. The third HTC metal plate 40 can be pre-fabricated or pre-processed, to delineate dicing streets 42, e.g. by dicing through most but not all of the thickness of the chip, and/or etching, molding, or embossing, for example, to delineate the individual chip submount structures. This avoids the lengthy and costly electroplating of thicker HTC metal 14 as described above. Subsequent processing steps for fabricating the submount and device structure can then proceed by steps similar to those described for any of the previous embodiments, or combinations of them, to provide an individual thermal dissipation structures 4, as shown in FIG. 4c, comprising a diamond layer 11, having a smooth surface 11a, on a metal substrate 44 comprising the deposited metal layers 12, 13 and 14 and the bonded metal plate 40.

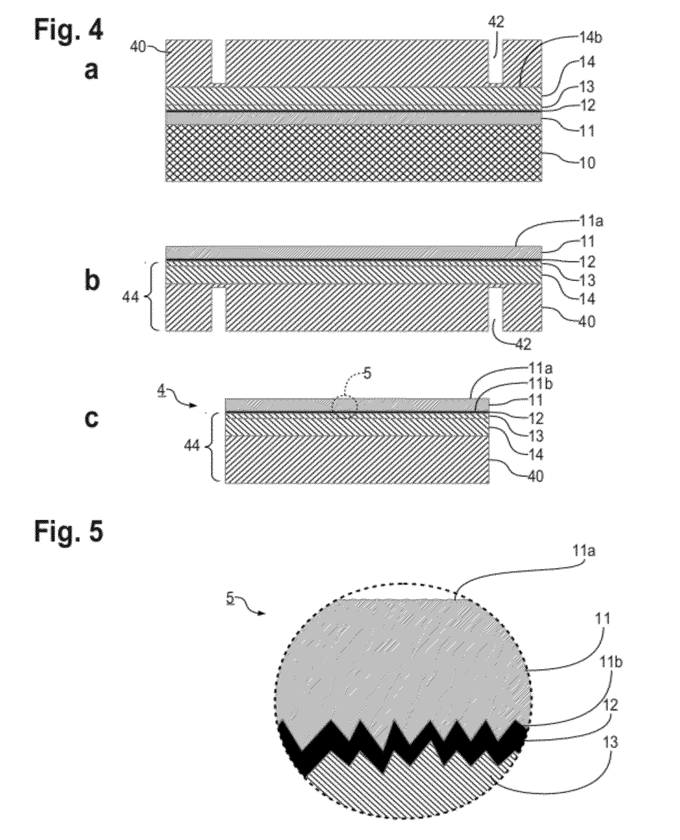

As illustrated schematically in FIG. 5, which shows an enlarged cross-sectional view of part 5 of the structure shown in FIG. 4c, the diamond layer of the thermal dissipation structure comprises a layer of high thermal conductivity (HTC) diamond 11 on a HTC metal 13, preferably copper or silver, and the diamond-metal interface comprises an adhesion layer 12, which is preferably Ta. The diamond layer is preferably non-conductive (undoped) and may have a thickness e.g. from about 3 μm to 30 μm, while the metal substrate may be significantly thicker. The adhesion layer 13 is preferably 2 nm to 500 nm thick, and more preferably less than 50 nm thick. The exposed surface 11a of the diamond layer is relatively smooth, having a surface roughness of <10 nm RMS, preferably ≦5 nm and more preferably ≦2 nm, i.e. controlled by the surface roughness of the polished sacrificial silicon layer on which it was formed. The diamond-metal interface 11b is relatively rough, and perhaps has a surface roughness of ˜1 μm RMS or more, but this interface is buried in the HTC substrate.

This method of fabrication described herein avoids the need for direct deposition of diamond on copper, and allows for depositing copper by electroplating or electroforming onto a diamond-coated Si wafer comprising an intermediary adhesion and plating base layer.

After removal of the silicon substrate, it provides a diamond layer with a smooth exposed surface, as deposited, with surface roughness determined by the sacrificial substrate, without the need for slow and expensive polishing. A layer of several microns of HTC diamond on a HTC metal such as copper provides for improved thermal dissipation, while avoiding the time and expense of growing a monolithic diamond structure.

In other variants of the preceding embodiments, or other alternative embodiments, the HTC metal layers for the HTC metal substrate may preferably comprise copper and silver; and alternatively may comprise HTC alloys such as a Cu—Ag. While gold may be used, it is both more expensive and has a lower thermal conductivity than copper and silver, so that in practice, copper and silver or their alloys are preferred. In other embodiments, the HTC substrate may alternatively comprise HTC composite materials, such as: Cu-diamond, Ag-diamond, carbon nanotube or graphene platelets-based nanocomposites, together with or instead of copper and silver.

For diamond on copper, the adhesion layer preferably comprises tantalum. The adhesion layer may alternatively be another refractory metal such as Nb, Ti, W or Mo or other metal with good adhesion to diamond. Tantalum is preferred because it is more ductile and thus can adapt to stress at the diamond-metal interface by plastic deformation.

Conveniently, the sacrificial substrate is silicon having a suitable surface roughness, i.e. a polished silicon wafer, which is readily available at reasonable cost and can withstand processing conditions required for diamond deposition thereon.

Although embodiments of the invention have been described and illustrated in detail, it is to be clearly understood that the same is by way of illustration and example only and not to be taken by way of limitation, the scope of the present invention being limited only by the appended claims.

1. A method for fabricating a device structure comprising a diamond on metal substrate for thermal dissipation, by steps comprising:
providing a sacrificial silicon substrate having a surface of a selected surface roughness,
providing thereon a layer of high thermal conductivity (HTC) diamond;
providing an adhesion layer on the layer of diamond;
providing thereon at least one layer of high thermal conductivity (HTC) metal to form an HTC metal substrate; and
removing the sacrificial substrate.

2. A method according to claim 1 wherein
the sacrificial substrate has a surface roughness of ≦10 nm RMS, and
the step of providing the layer of HTC diamond comprises depositing a layer of HTC diamond having a grain size ≧100 nm.

3. A method according to claim 1 wherein the step of providing the layer of HTC diamond comprises providing a layer of non-conductive diamond.

4. A method according to claim 1 wherein the HTC metal layer is selected from the group consisting of copper, silver, an alloy of copper, an alloy of silver, and a copper-silver alloy.

5. A method according to claim 1 wherein the step of providing an adhesion layer comprises depositing a metal selected from the group consisting of tantalum, niobium, titanium, molybdenum, tungsten, other metals having good adhesion to diamond, and mixtures thereof.

6. A method according to claim 1 wherein the step of providing at least one layer of HTC metal to form a metal substrate comprises:
a) depositing a first layer of HTC metal on the adhesion layer as a plating base layer and
b) electroforming a second layer of HTC metal on the base layer, and planarizing the surface of the resulting second layer of HTC metal.

7. A method according to claim 6 wherein the step of providing at least one layer of HTC metal to form a metal substrate further comprises:
bonding another layer of HTC metal.

8. A method according to claim 6 wherein:
the step of providing an adhesion layer comprises sputtering the adhesion layer; and
the step of depositing the first layer of HTC metal comprises sputtering the first layer of HTC metal onto the adhesion layer, without breaking vacuum.

9. A method according to claim 6 further comprising dicing the resulting diamond on HTC metal layers to define a plurality of individual heat dissipation structures.

10. A method according to claim 1 wherein the step of providing a layer of HTC diamond comprises:
masking or patterning the sacrificial substrate; and
selectively providing a patterned layer of HTC diamond on the sacrificial substrate.

11. A method according to claim 10 wherein the step of providing at least one layer of HTC metal to form a metal substrate comprises:
depositing a first layer of HTC metal on the adhesion layer as a plating base layer; and electroforming a second layer of HTC metal on the base layer;
optionally, bonding a third layer of HTC metal; and
subsequently, dicing the resulting structure to define a plurality of individual heat dissipation structures.

12. A method according to claim 10 wherein the step of providing at least one layer of a high thermal conductivity metal to form a metal substrate comprises:
depositing a first layer of HTC metal on the adhesion layer as a plating base layer;
selectively masking the resulting surface; and
electroforming a second layer of HTC metal to define a plurality of individual heat dissipation structures;
and optionally,
after electroforming the second layer of HTC metal to define individual heat dissipation structures, planarizing the resulting surface and bonding a removable carrier layer thereto, before removing the sacrificial substrate layer.

13. A method according to claim 1 further comprising any one of the following steps:
a) defining contact metallization on the resulting diamond surface;
b) defining contact metallization on the resulting diamond surface and bonding or connecting a semiconductor device to the contact metallization;
c) bonding a semiconductor device to the diamond surface.

14. A device structure comprising a chip submount for thermal dissipation comprising: a layer of HTC diamond on a HTC metal substrate fabricated by the method steps of claim 1.

15. A device structure according to claim 14 wherein the diamond layer comprises a device mounting surface having a surface roughness of <10 nm RMS, preferably <5 nm RMS, and more preferably <2 nm RMS.

16. A device structure according to claim 15 further comprising a semiconductor device thermally coupled to the device mounting surface.

17. A device structure for thermal dissipation comprising:
a layer of high thermal conductivity (HTC) diamond having a grain size of greater than ≧100 nm on a HTC metal substrate;
the diamond layer having a device mounting surface and an interface with the HTC metal substrate comprising an adhesion layer; and
the interface of the layer of HTC diamond with the HTC metal substrate having a surface roughness substantially larger than the surface roughness of the device mounting surface of the HTC diamond layer.

18. A device structure according to claim 17 wherein the device mounting surface of the HTC diamond layer has a surface roughness of ≦10 nm, preferably ≦5 nm and more preferably ≦2 nm RMS.

19. A device structure according to claim 17 wherein the HTC metal substrate comprises at least one HTC metal layer selected from the group of HTC metals consisting copper, silver, and alloys thereof and wherein the adhesion layer comprises a layer of a metal selected from the group consisting of tantalum, niobium, titanium, molybdenum, tungsten, other metals having good adhesion to diamond, and mixtures thereof.

20. A device structure according to claim 17 wherein the HTC diamond layer is non-conductive.

21. A device structure according to claim 17 wherein the diamond layer has a thickness from 3 to 30 μm and wherein the adhesion layer has a thickness from 2 nm to 500 nm.

22. A method for forming a device structure for thermal dissipation comprising a HTC diamond layer having a surface of a selected surface roughness, comprising:
providing a sacrificial substrate having a surface of the selected surface roughness;
providing thereon a layer of HTC diamond;
providing at least one layer of a HTC material to provide a HTC substrate; and
removing the sacrificial substrate to expose the diamond layer having a surface of the selected surface roughness on the HTC substrate.
